(19) United States
(12) Patent Application Publication
(10) Pub. No.: US 2024/0206181 A1
(43) Pub. Date: Jun. 20, 2024

(54) MEMORY DEVICES AND METHODS FOR FORMING THE SAME

(71) Applicant: YANGTZE MEMORY TECHNOLOGIES CO., LTD., Wuhan (CN)

(72) Inventors: Di Wang, Wuhan (CN); Yuancheng Yang, Wuhan (CN); Lei Liu, Wuhan (CN); Tao Yang, Wuhan (CN); Kun Zhang, Wuhan (CN); Dongxue Zhao, Wuhan (CN); Wenxi Zhou, Wuhan (CN); Zhiliang Xia, Wuhan (CN); Zongliang Huo, Wuhan (CN)

(21) Appl. No.: 18/090,915

(22) Filed: Dec. 29, 2022

(30) Foreign Application Priority Data
Dec. 20, 2022 (CN) 202211642373.X

(51) Int. Cl. H10B 43/40; H01L 23/528; H10B 41/27; H10B 41/40; H10B 43/27

(52) U.S. Cl. CPC H10B 43/40; H01L 23/5283; H10B 41/27; H10B 41/40; H10B 43/27

(57) ABSTRACT

A memory device includes a semiconductor layer; a peripheral circuit disposed on the semiconductor layer; and an array of memory cells disposed aside the peripheral circuit on the semiconductor layer. Each of the memory cells includes a semiconductor body extending in a first direction, a first end of the semiconductor body is in contact with the semiconductor layer; a word line gate extending in a second direction perpendicular to the first direction; a plate line gate extending in the second direction; and a dielectric layer disposed between the semiconductor body and the word line gate and the plate line gate.

### CROSS-REFERENCE TO RELATED APPLICATIONS

This application claims the benefit of priority to Chinese Application No. 202211642373.X, filed Dec. 20, 2022, which is incorporated herein by reference in its entirety.

### BACKGROUND

The present disclosure relates to memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a memory device is disclosed. The memory device includes a semiconductor layer; a peripheral circuit disposed on the semiconductor layer; and an array of memory cells disposed aside the peripheral circuit on the semiconductor layer. Each of the memory cells includes a semiconductor body extending in a first direction, a first end of the semiconductor body is in contact with the semiconductor layer; a word line gate extending in a second direction perpendicular to the first direction; a plate line gate extending in the second direction; and a dielectric layer disposed between the semiconductor body and the word line gate and the plate line gate.

In some implementations, the plate line gate includes conductive lines extending in the second direction parallel to the word line gate.

In some implementations, the semiconductor body and the semiconductor layer comprise a same semiconductor material.

In some implementations, the memory device further includes a bit line extending in a third direction perpendicular to the first direction and the second direction. A second end of the semiconductor body is in contact with the bit line.

In some implementations, the memory device further includes a contact disposed between the bit line and the second end of the semiconductor body.

In some implementations, the semiconductor layer includes a memory area and a peripheral area, the array of memory cells is disposed in the memory area, and the peripheral circuit is disposed in the peripheral area.

In a further aspect, a method for forming a memory device is disclosed. A peripheral circuit is formed on a peripheral area of a first semiconductor layer. A stack including interleaved first layers and second layers is formed on a memory area of the first semiconductor layer. A channel structure is formed in the stack extending in a first direction. A bit line is formed in contact with the channel structure.

In some implementations, interleaved first dielectric layers and second dielectric layers are formed on the peripheral area and the memory area of the first semiconductor layer.

In some implementations, the first dielectric layers and the second dielectric layers on the peripheral area are removed.

In some implementations, a staircase structure is formed at an edge of the stack.

In some implementations, the second dielectric layers are replaced with at least a word line gate and a plate line gate extending in a second direction perpendicular to the first direction.

In some implementations, the second dielectric layers are removed to form a plurality of cavities. The word line gate and the plate line gate are formed in the plurality of cavities.

In some implementations, interleaved first dielectric layers and second semiconductor layers are formed on the memory area and the peripheral area of the first semiconductor layer.

In some implementations, the first dielectric layers and the second semiconductor layers extend in a second direction perpendicular to the first direction.

In some implementations, a portion of the stack on the peripheral area of the first semiconductor layer is removed. A staircase structure is formed at an edge of the stack on the memory area of the first semiconductor layer.

In some implementations, a channel hole is formed penetrating the dielectric stack to expose the semiconductor layer. A third dielectric layer is formed on sidewalls of the channel hole. A semiconductor body is formed in the channel hole.

In some implementations, the bit line is formed extending in a third direction perpendicular to the first direction and the second direction and in contact with a semiconductor body of the channel structure.

In some implementations, a contact extending in the first direction is formed in contact with the bit line and the semiconductor body of the channel structure.

In some implementations, the semiconductor body and the first semiconductor layer include a same semiconductor material.

In still a further aspect, a system is disclosed. The system includes a memory device and a memory controller. The memory device includes a semiconductor layer; a peripheral circuit disposed on the semiconductor layer; and an array of memory cells disposed aside the peripheral circuit on the semiconductor layer. Each of the memory cells includes a semiconductor body extending in a first direction, a first end of the semiconductor body is in contact with the semiconductor layer; a word line gate extending in a second direction perpendicular to the first direction; a plate line gate extending in the second direction; and a dielectric layer disposed between the semiconductor body and the word line gate and the plate line gate. The memory controller coupled to the memory device and configured to control operations of the array of memory cells through the peripheral circuit.

### BRIEF DESCRIPTION OF THE DRAWINGS

The accompanying drawings, which are incorporated herein and form a part of the specification, illustrate implementations of the present disclosure and, together with the description, further serve to explain the present disclosure and to enable a person skilled in the pertinent art to make and use the present disclosure.

FIG. 1 illustrates a schematic view of a cross-section of a memory device, according to some aspects of the present disclosure.

FIG. 2 illustrates a schematic view of a cross-section of a memory cell, according to some aspects of the present disclosure.

FIG. 3 illustrates a side view of a cross-section of a memory device, according to some aspects of the present disclosure.

FIG. 4 illustrates a side view of a cross-section of a memory device, according to some aspects of the present disclosure.

FIGS. 5-13 illustrate a fabrication process for forming a memory device, according to some aspects of the present disclosure.

FIG. 14 illustrates a flowchart of a method for forming a memory device, according to some aspects of the present disclosure.

FIGS. 15-21 illustrate a fabrication process for forming a memory device, according to some aspects of the present disclosure.

FIG. 22 illustrates a flowchart of a method for forming a memory device, according to some aspects of the present disclosure.

FIG. 23 illustrates a block diagram of an exemplary system having a memory device, according to some aspects of the present disclosure.

FIG. 24A illustrates a diagram of an exemplary memory card having a memory device, according to some aspects of the present disclosure.

FIG. 24B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

Transistors are used as the switch or selecting devices in the memory cells of some memory devices. However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, as the number of memory cells keeps increasing, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, the present disclosure introduces a memory device having a vertical arrangement of the source/drain terminals, a word line gate, and a plate line gate to select and store data in the memory device. Compared to the existing memory cells, the memory device in the present disclosure has vertically arranged transistors (i.e., the drain and source are overlapped in the plan view) that can reduce the area of the transistor as well as simplify the layout of the interconnect structures, e.g., metal wiring, the word lines and bit lines, which can reduce the fabrication complexity and improve the yield. In addition, the memory device in the present disclosure does not need a capacitor storage device to store data in the memory device.

Furthermore, consistent with the scope of the present disclosure, according to some aspects of the present disclosure, the memory cell array having vertical transistors and the peripheral circuits of the memory cell array can be formed on the same wafer in a side-by-side manner, i.e., next to one another. The number of wafers needed to fabricate the same number of memory devices and the complexity involved in the bonding process can be reduced compared with the face-to-face bonding scheme.

In some implementations, the vertical transistors disclosed herein may include dynamic flash memories (DFM), which is a capacitor-less type of random access memory (RAM). The DFM uses a dual gate surrounding gate transistor (SGT) to eliminate capacitors and increase the bit density of memory.

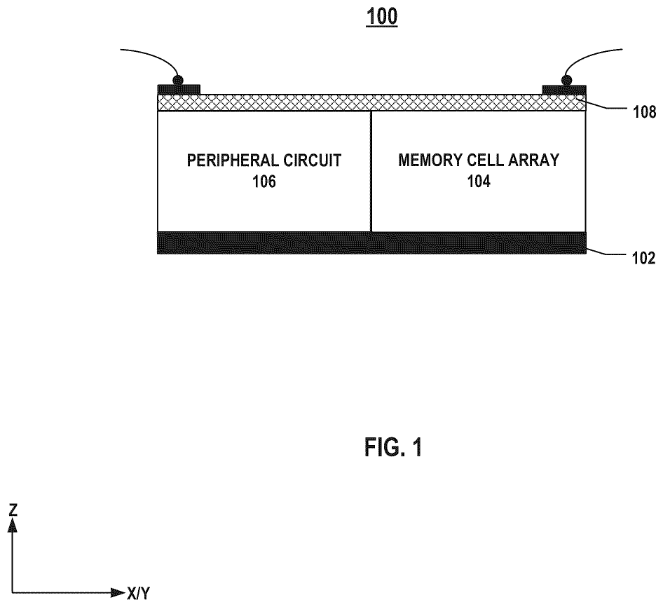

FIG. 1 illustrates a schematic view of a cross-section of a memory device 100, according to some aspects of the present disclosure. As shown in FIG. 1, memory device 100 may include a memory cell array region 104 and a peripheral circuit region 106 arranged side-by-side in the same device plane.

A memory cell array can be formed in memory cell array region 104, and the peripheral circuits of the memory cell array can be formed in peripheral circuit region 106 disposed beside memory cell array region 104. The peripheral circuits (a.k.a. control and sensing circuits) may include any suitable digital, analog, and/or mixed-signal circuits used for facilitating the operations of the memory cell array. For example, the peripheral circuit may include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits may use complementary metal-oxide-semiconductor (CMOS) technology which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

In some implementations, memory device 100 also includes a substrate 102. As described below with respect to the fabrication process, substrate 102 is a carrier substrate (a.k.a. a handle substrate) bonded to the device plane having the memory cell array and peripheral circuits to hold the memory cell array and peripheral circuits, according to some implementations. Substrate 102 may further include a semiconductor layer, for example, part of a thinned silicon substrate from which the memory cell array and peripheral circuits are formed in the device plane. As shown in FIG. 1, memory device 100 may further include a pad-out interconnect layer 108 for pad-out purposes, i.e., interconnecting with external devices using contact pads on which bonding wires can be soldered. Pad-out interconnect layer 108 and substrate 102 may be disposed on opposite sides of the device plane having the memory cell array and peripheral circuits in a z-direction, e.g., the first direction. In other words, the memory cell array and peripheral circuits are disposed vertically between pad-out interconnect layer 108 and substrate 102 in memory device 100, according to some implementations.

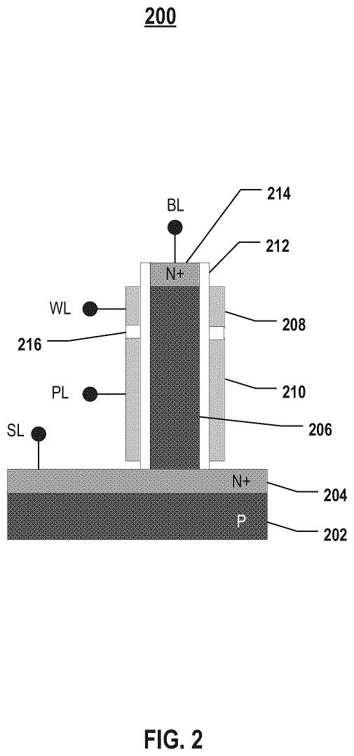

FIG. 2 illustrates a schematic view of a cross-section of a memory cell 200, according to some aspects of the present disclosure. In some implementations, the memory cell array includes an array of memory cells 200. For ease of description, a DFM cell array may be used as an example for describing the memory cell array in the present disclosure. But it is understood that the memory cell array is not limited to DFM cell array and may include any other suitable types of memory cell arrays that can use transistors as selecting device and storage unit.

Memory cell 200 includes a semiconductor body 206 formed on a semiconductor layer 202, e.g., a semiconductor substrate. In some implementations, semiconductor body 206 may include P type or intrinsic conductivity type silicon. In some implementations, semiconductor layer 202 may include a silicon substrate. A first end 204 and a second end 214 of semiconductor body 206 may include N+ layers. As used herein the N+ layers are semiconductor regions that contain a donor impurity in high concentration. In some implementations, first end 204 and second end 214 function as the source and the drain of the transistor, e.g., the memory cell. Portions of semiconductor body 206 between first end 204 and second end 214 may function as the channel region of the transistor. Around semiconductor body 206, a dielectric layer 212 may be formed as a gate insulating layer of the transistor. A word line gate 208 and a plate line gate 210 may be formed around dielectric layer 212 and may function as gate conductor layers. In some implementations, word line gate 208 and plate line gate 210 may be further isolated from each other by a dielectric layer 216.

The channel region, which is a portion of semiconductor body 206 between first end 204 and second end 214, may be constituted by a first channel layer surrounded by plate line gate 210 and a second channel layer surrounded by word line gate 208. Accordingly, first end 204 and second end 214 that function as the source and the drain, the channel region, dielectric layer 212, word line gate 208, and plate line gate 210 constitute memory cell 200. First end 204 that functions as the source is connected to a source line SL, second end 214 that functions as the drain is connected to a bit line BL, plate line gate 210 is connected to a plate line PL, and word line gate 208 is connected to a word line WL. In some implementations, the structure is such that the gate capacitance of plate line gate 210 to which the plate line PL is connected is larger than the gate capacitance of word line gate 208 to which the word line WL is connected.

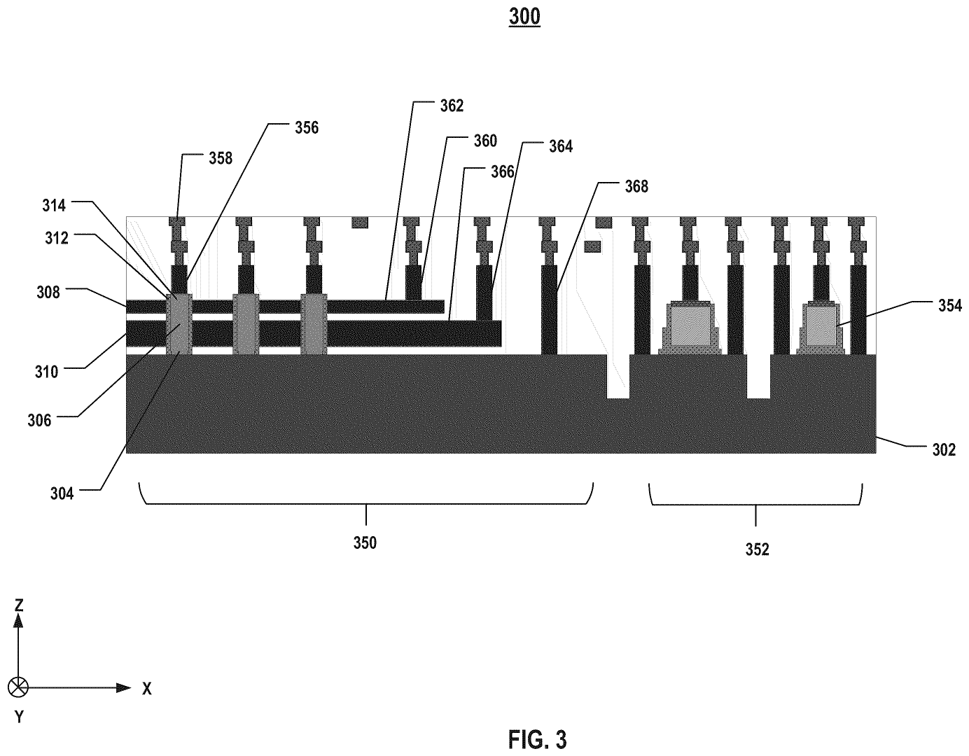

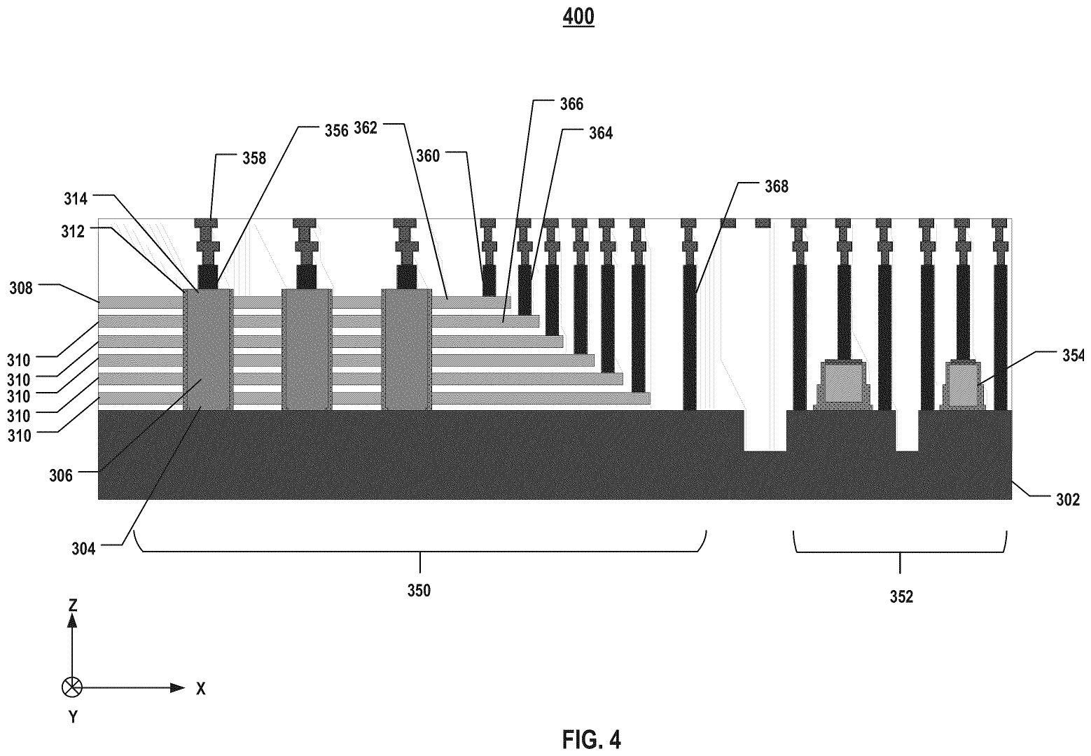

In some implementations, to make the gate capacitance of plate line gate 210 to which the plate line PL is connected larger than the gate capacitance of word line gate 208 to which the word line WL is connected, the gate length of plate line gate 210 may be made longer than the gate length of word line gate 208. Alternatively, instead of making the gate length of plate line gate 210 longer than the gate length of word line gate 208, as shown in FIG. 3, plate line gate 210 may be formed by a plurality of gates, as shown in FIG. 4. The channel region between first end 204 and second end 214 is electrically isolated from semiconductor layer 202 and functions as a floating body.

FIG. 3 illustrates a side view of a cross-section of a memory device 300, according to some aspects of the present disclosure. As shown in FIG. 3, memory device 300 includes a memory area 350 and a peripheral area 352 formed on a semiconductor layer 302, e.g., a silicon substrate. One or more than one peripheral circuit including one or more than one peripheral device 354 is formed in peripheral area 352 on semiconductor layer 302. In some implementations, the peripheral circuits may include any suitable digital, analog, and/or mixed-signal circuits used for facilitating the operations of the memory cell array.

Memory device 300 further includes a plurality of memory cells formed in memory area 350 on semiconductor layer 302. Each memory cell includes a semiconductor body 306. A first end 304 and a second end 314 are formed at two sides of semiconductor body 306 and may include N+ layers. First end 304 and second end 314 function as the source and the drain of the memory cell. Portions of semiconductor body 306 between first end 304 and second end 314 may function as the channel region of the memory cell. Around semiconductor body 306, a dielectric layer 312 may be formed as a gate insulating layer of the memory cell. A word line gate 308 and a plate line gate 310 may be formed around dielectric layer 312 and may function as gate conductor layers. In some implementations, word line gate 308 and plate line gate 310 may be isolated from each other.

As shown in FIG. 3, semiconductor body 306 extends along the z-direction, and first end 304 and second end 314, which function as the source/drain, are formed at the top and the bottom of semiconductor body 306. Word line gate 308 and plate line gate 310 may be parallel to each other and extend along a x-direction, e.g., a second direction, perpendicular to the z-direction. A contact 356 is formed above semiconductor body 306 in contact with second end 314, and a bit line 358 is formed above contact 356. As shown in FIG. 3, bit line 358 extends along a y-direction, a third direction, perpendicular to the x-direction and the z-direction. A contact 360 is formed above a word line 362, a contact 364 is formed above a plate line 366, and a contact 368 is formed above semiconductor layer 302.

In some implementations, word line gate 308 and plate line gate 310 may include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, word line gate 308 and plate line gate 310 may include doped polysilicon, i.e., a gate poly. In some implementations, word line gate 308 and plate line gate 310 may include multiple conductive layers, such as a W layer over a TiN layer. It is understood that word line 362 and plate line 366 may be a continuous conductive structure in some examples. In other words, word line gate 308 and plate line gate 310 may be viewed as part of word line 362 and plate line 366 that forms the gate structures.

In some implementations, semiconductor body 306 may be formed from semiconductor layer 302 (e.g., by etching or epitaxy) and thus, may have the same semiconductor material (e.g., single crystalline silicon) as semiconductor layer 302. In some implementations, dielectric layer 312 may include silicon oxide, i.e., gate oxide.

FIG. 4 illustrates a side view of a cross-section of a memory device 400, according to some aspects of the present disclosure. As shown in FIG. 4, memory device 400 is similar to memory device 300, but plate line gate 310 in FIG. 4 may include multiple conductive layers parallel to each other. It is understood that in FIG. 4, contact 364 and plate line 366 corresponding to plate line gate 310 may also include multiple contacts and plate lines.

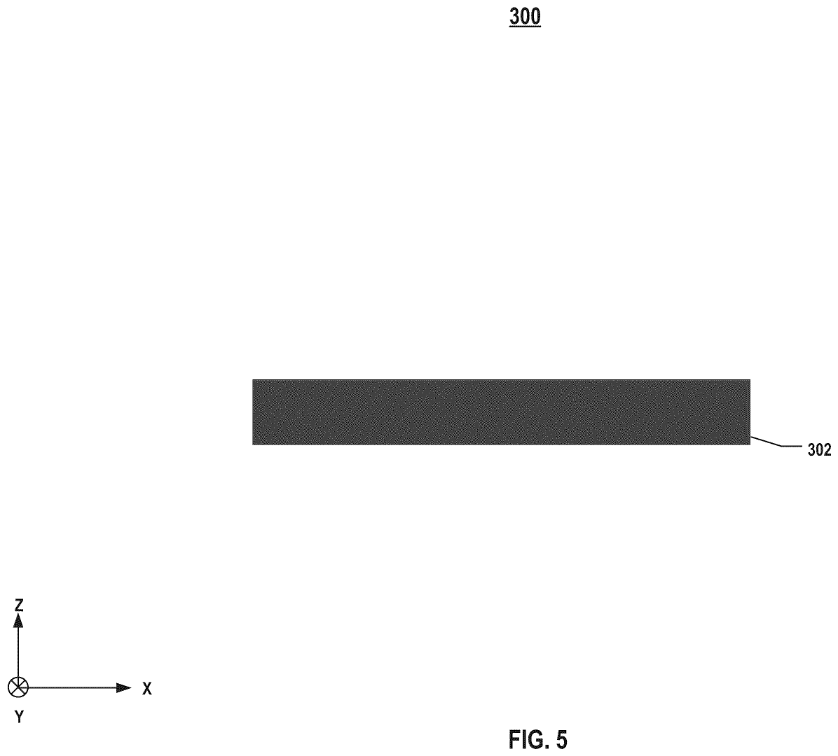

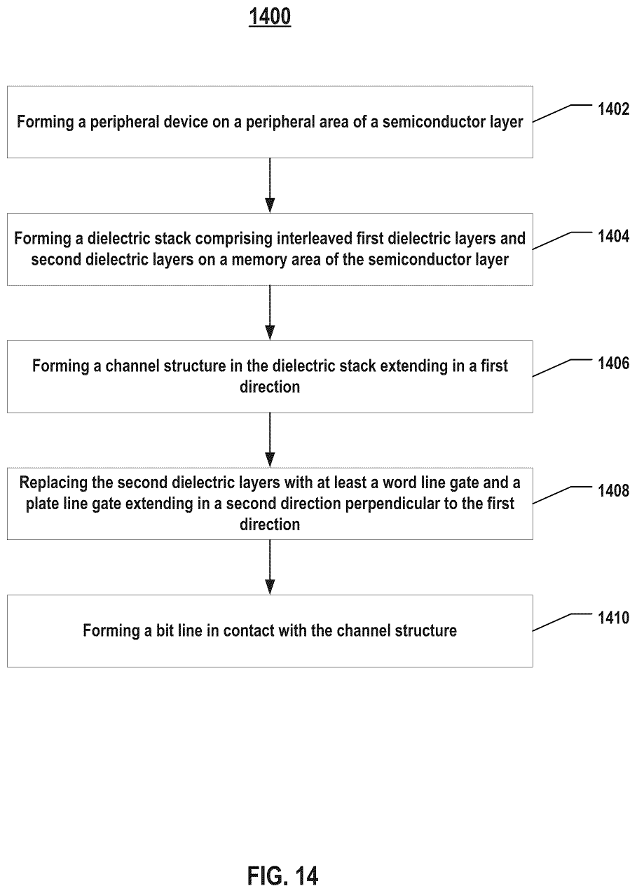

FIGS. 5-13 illustrate a fabrication process for forming memory device 300, according to some aspects of the present disclosure. FIG. 14 illustrates a flowchart of a method 1400 for forming memory device 300, according to some aspects of the present disclosure. For the purpose of better describing the present disclosure, the memory device 300 in FIGS. 5-13 and method 1400 in FIG. 14 will be discussed together. It is understood that the operations shown in method 1400 are not exhaustive and that other operations may be performed as well before, after, or between any of the illustrated operations. Further, some of the operations may be performed simultaneously, or in a different order than shown in FIGS. 5-13 and FIG. 14. It is also understood that FIGS. 5-13 illustrate memory device 300 having the gate length of plate line gate 310 longer than the gate length of word line gate 308 as an example, and other implementations that plate line gate 310 is formed by a plurality of gates may also be suitable for the fabrication process.

As shown in FIG. 5, semiconductor layer 302 is provided as a substrate of the fabrication process. In some implementations, semiconductor layer 302 may be a silicon substrate.

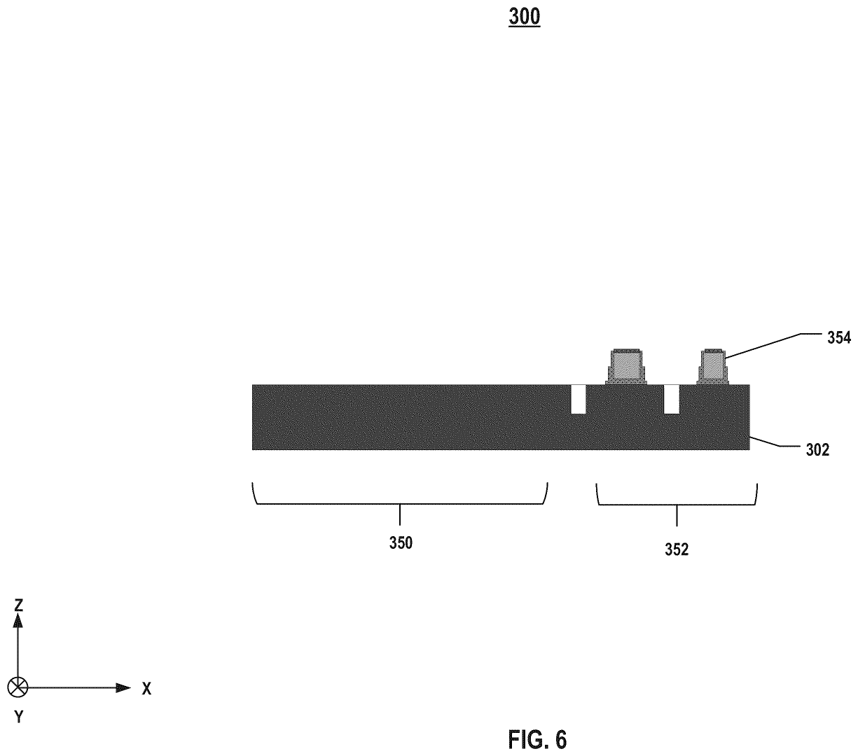

As shown in FIG. 6 and operation 1402 in FIG. 14, peripheral device 354 is formed on peripheral area 352 of semiconductor layer 302. In some implementations, peripheral device 354 is used to form the peripheral circuit including one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits may use CMOS technology which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

In some implementations, one or more than one trench may be formed in semiconductor layer 302 between memory area 350 and peripheral area 352. In some implementations, a dielectric material, e.g., silicon oxide, may be filled in the trench, as shown in FIG. 6.

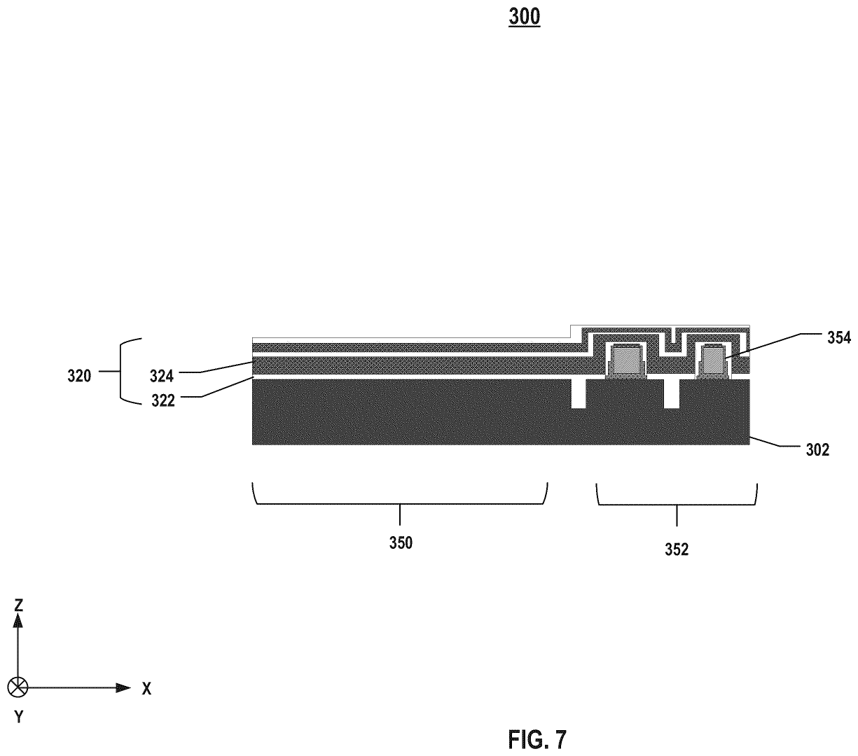

As shown in FIG. 7 and operation 1404 in FIG. 14, a dielectric stack 320 including interleaved first dielectric layers 322 and second dielectric layers 324 is formed in memory area 350 on semiconductor layer 302. In some implementations, first dielectric layers 322 may include silicon oxide, and second dielectric layers 324 may include silicon nitride. In some implementations, first dielectric layers 322 and second dielectric layers 324 may be formed by one or more thin film deposition processes including, but not limited to, chemical vapor deposition (CVD), physical vapor deposition (PVD), atomic layer deposition (ALD), electroplating, electroless plating, or any combination thereof.

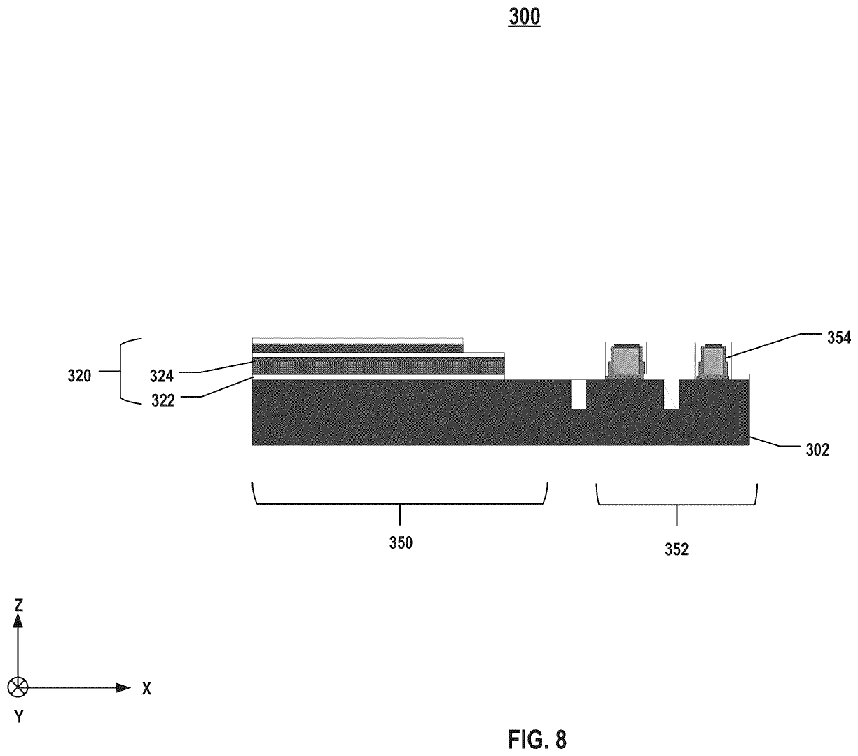

As shown in FIG. 8, first dielectric layers 322 and second dielectric layers 324 on peripheral area 352 may be then removed, and a staircase structure may be formed at an edge of dielectric stack 320 on memory area 350. In some implementations, first dielectric layers 322 and second dielectric layers 324 may be removed by a plurality of processes including, but not limited to, photolithography, dry/wet etch, chemical mechanical polishing (CMP), and any other suitable processes.

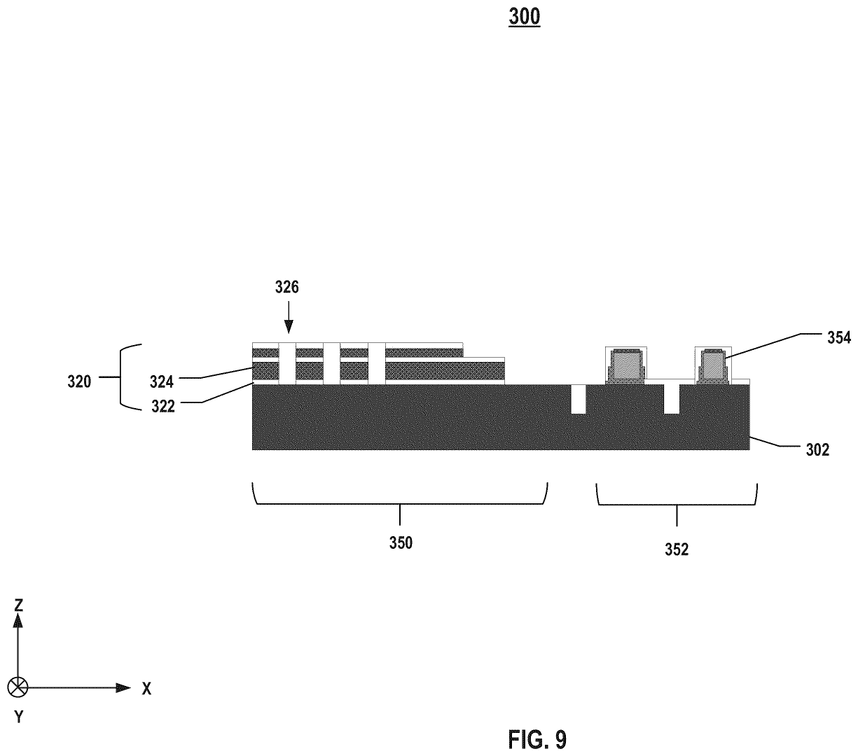

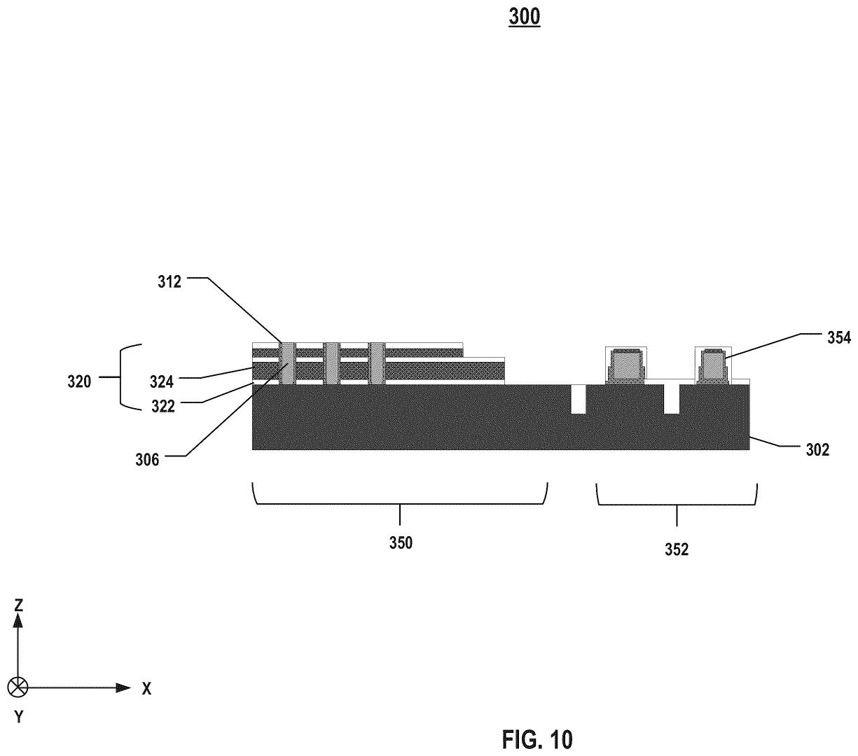

As shown in FIGS. 9-10 and operation 1406 in FIG. 14, a channel structure is formed in dielectric stack 320 extending in the z-direction. As shown in FIG. 9, a channel hole 326 penetrating dielectric stack 320 is formed to expose semiconductor layer 302. In some implementations, channel hole 326 may be formed by a plurality of processes including, but not limited to, photolithography, dry/wet etch, and any other suitable processes. Then, as shown in FIG. 10, dielectric layer 312 is formed on sidewalls of channel hole 326, and semiconductor body 306 is formed in channel hole 326.

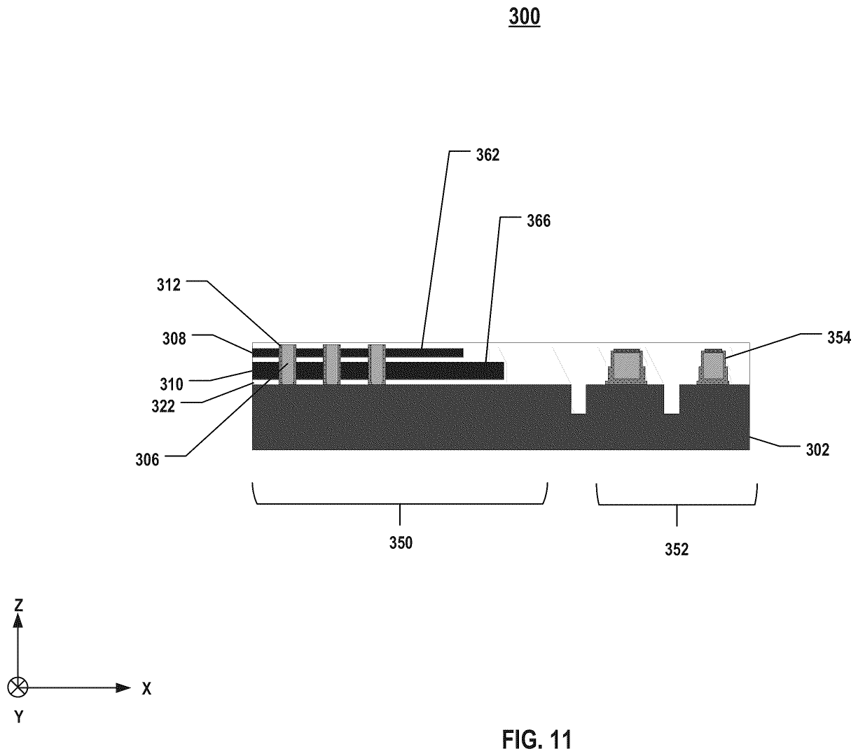

As shown in FIG. 11 and operation 1408 in FIG. 14, second dielectric layers 324 are replaced with word line 362, including word line gate 308, and plate line 366, including plate line gate 310, extending in the x-direction perpendicular to the z-direction. In some implementations, second dielectric layers 324 are removed by dry/wet etch and any other suitable processes to form a plurality of cavities. Then, word line 362 and plate line 366 are formed in the plurality of cavities. In some implementations, word line 362 and plate line 366 may be formed by thin film deposition, thermal growth, and any other suitable processes. In some implementations, word line 362 and plate line 366 may include any suitable conductive materials, such as polysilicon, metals (e.g., W, Cu, Al, etc.), metal compounds (e.g., TiN, TaN, etc.), or silicides. For example, word line 362 and plate line 366 may include doped polysilicon, i.e., a gate poly. In some implementations, word line 362 and plate line 366 may include multiple conductive layers, such as a W layer over a TiN layer.

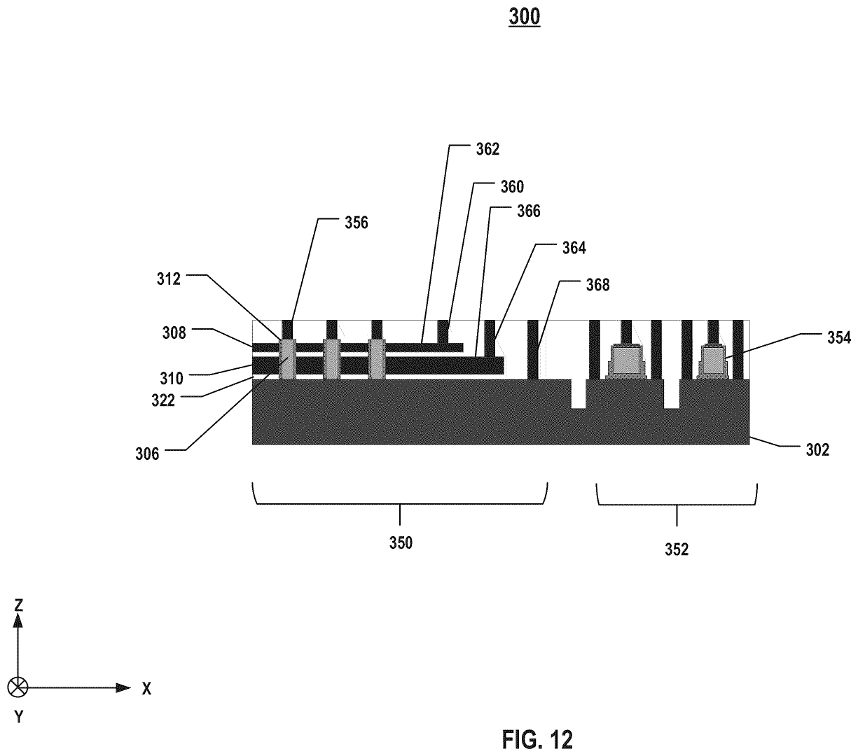

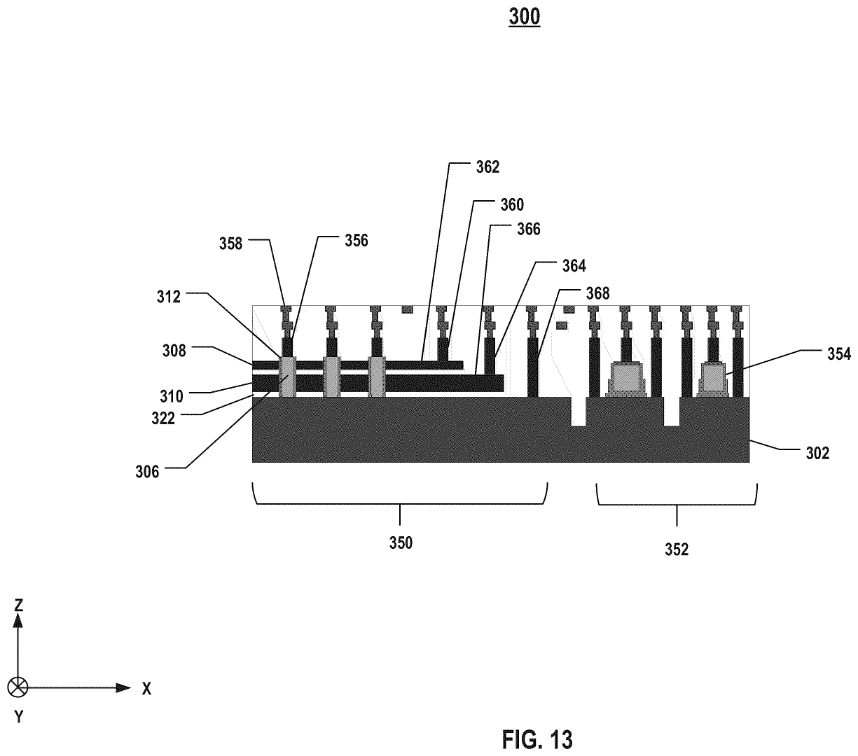

As shown in FIG. 12, a plurality of contacts 356, 360, 364, and 368 are formed. In some implementations, contact 356 is formed above semiconductor body 306 in contact with second end 314, contact 360 is formed above word line 362, contact 364 is formed above plate line 366, and contact 368 is formed above semiconductor layer 302. As shown in FIG. 13 and operation 1410 in FIG. 14, bit line 358 is formed above contact 356 extending along the y-direction perpendicular to the x-direction and the z-direction.

By utilizing the fabrication method 1400, memory device 300 may have a vertical arrangement of the source/drain terminals, which can reduce the area of the transistor as well as simplify the layout of the interconnect structures and reduce the fabrication complexity. In addition, memory device 300 does not need a capacitor storage device to store data. Furthermore, the memory cell array and the peripheral circuits can be formed on the same wafer in a side-by-side manner, and the number of wafers needed to fabricate the same number of memory devices and the complexity involved in the bonding process can be reduced.

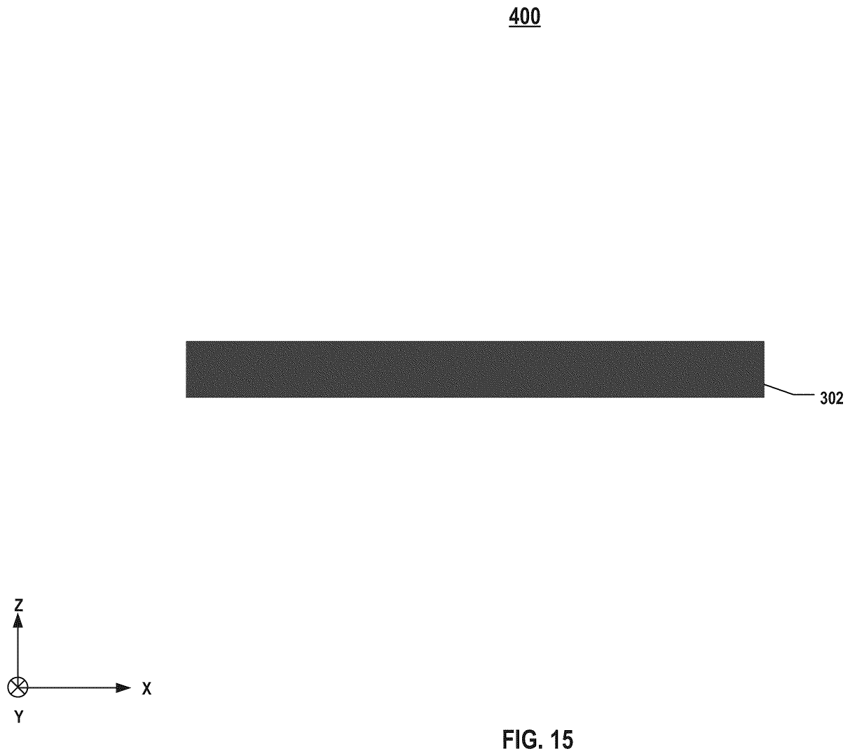

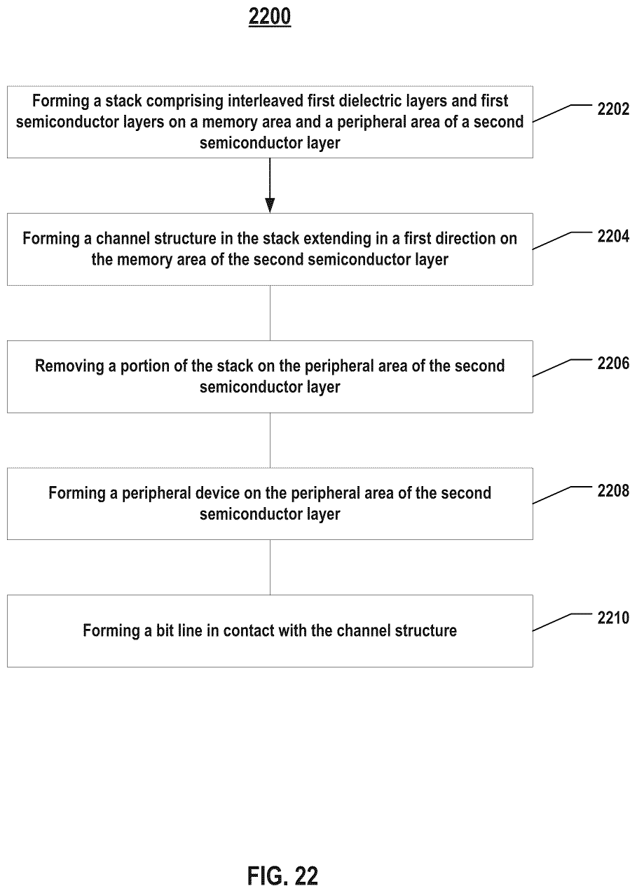

FIGS. 15-21 illustrate a fabrication process for forming memory device 400, according to some aspects of the present disclosure. FIG. 22 illustrates a flowchart of a method 2200 for forming memory device 400, according to some aspects of the present disclosure. For the purpose of better describing the present disclosure, the memory device 400 in FIGS. 15-21 and method 2200 in FIG. 22 will be discussed together. It is understood that the operations shown in method 2200 are not exhaustive and that other operations may be performed as well before, after, or between any of the illustrated operations. Further, some of the operations may be performed simultaneously, or in a different order than shown in FIGS. 15-21 and FIG. 22. It is also understood that FIGS. 15-21 illustrate memory device 400 having plate line gate 310 formed by a plurality of gates as an example, and other implementations that plate line gate 310 is formed by a single gate may also be suitable for the fabrication process.

As shown in FIG. 15, semiconductor layer 302 is provided as a substrate of the fabrication process. In some implementations, semiconductor layer 302 may be a silicon substrate.

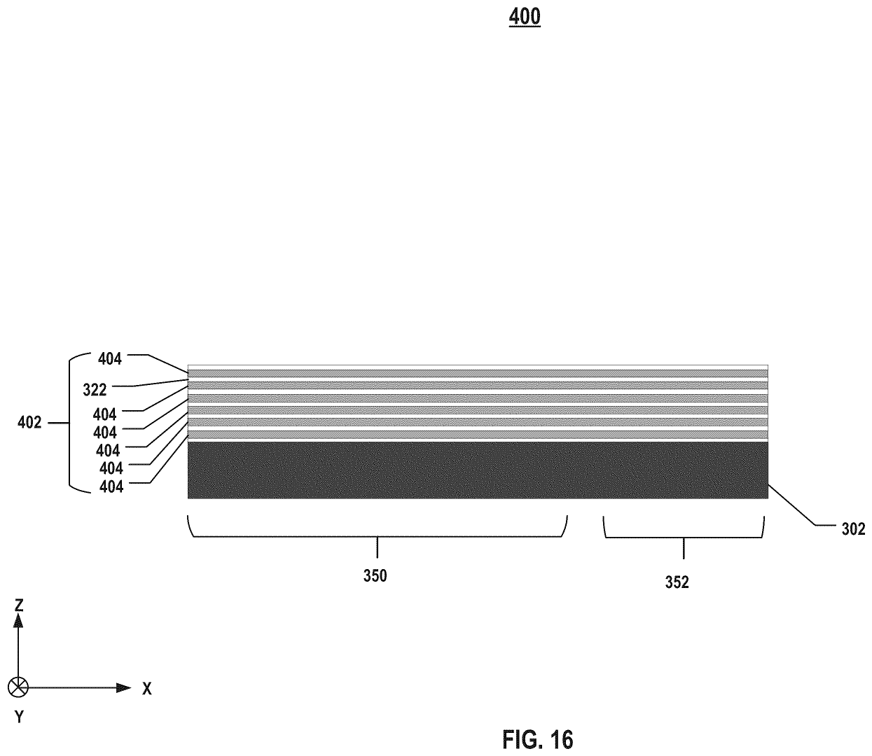

As shown in FIG. 16 and operation 2202 in FIG. 22, a stack 402 including interleaved first dielectric layers 322 and semiconductor layers 404 is formed on memory area 350 and peripheral area 352 of semiconductor layer 302. In some implementations, first dielectric layers 322 may include silicon oxide. In some implementations, semiconductor layers 404 may include any suitable semiconductor or conductive materials, such as polysilicon, metals (e.g., W, Cu, Al, etc.), metal compounds (e.g., TiN, TaN, etc.), or silicides. In some implementations, first dielectric layers 322 and semiconductor layers 404 may be formed by one or more thin film deposition processes including, but not limited to, CVD, PVD, ALD, electroplating, electroless plating, or any combination thereof.

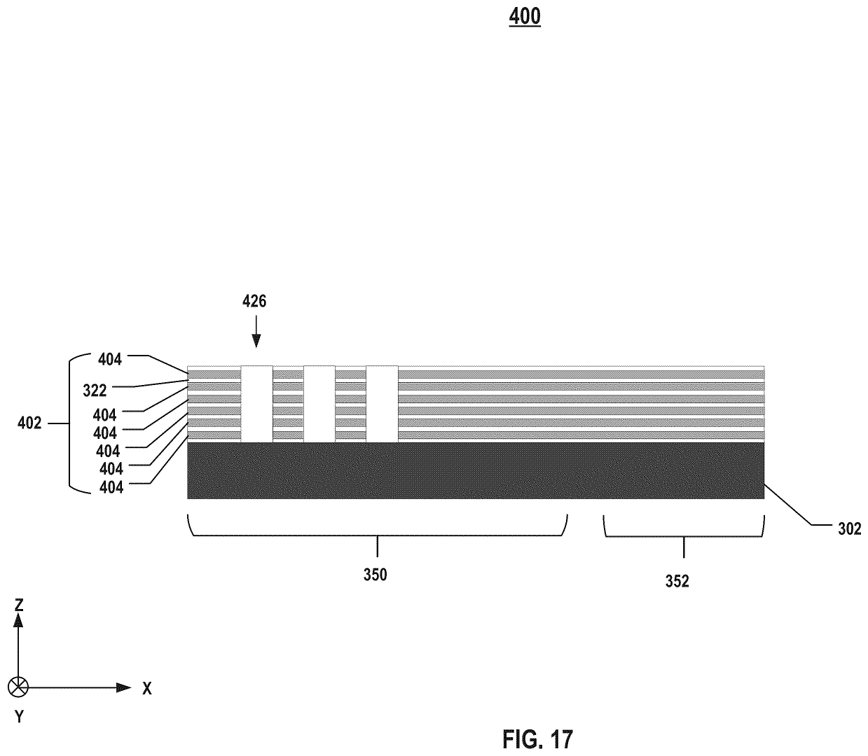

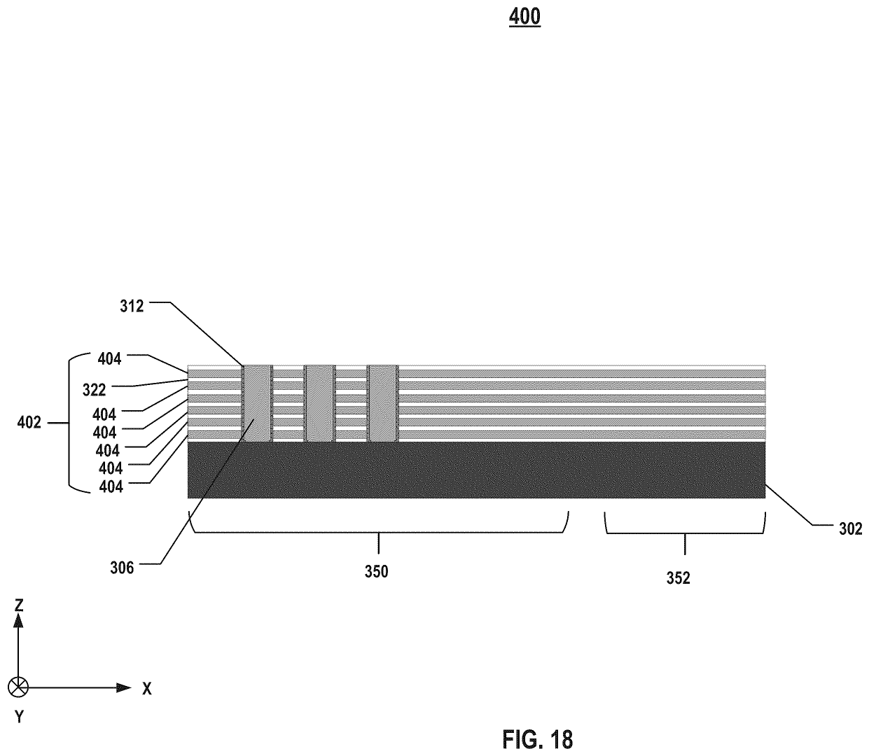

As shown in FIGS. 17-18 and operation 2204 in FIG. 22, a channel structure is formed in stack 402 extending in the z-direction in memory area 350 on semiconductor layer 302. As shown in FIG. 17, a channel hole 426 is formed penetrating stack 402 extending in the z-direction to expose semiconductor layer 302. Then, as shown in FIG. 18, dielectric layer 312 is formed on sidewalls of channel hole 426, and semiconductor body 306 is formed in channel hole 426.

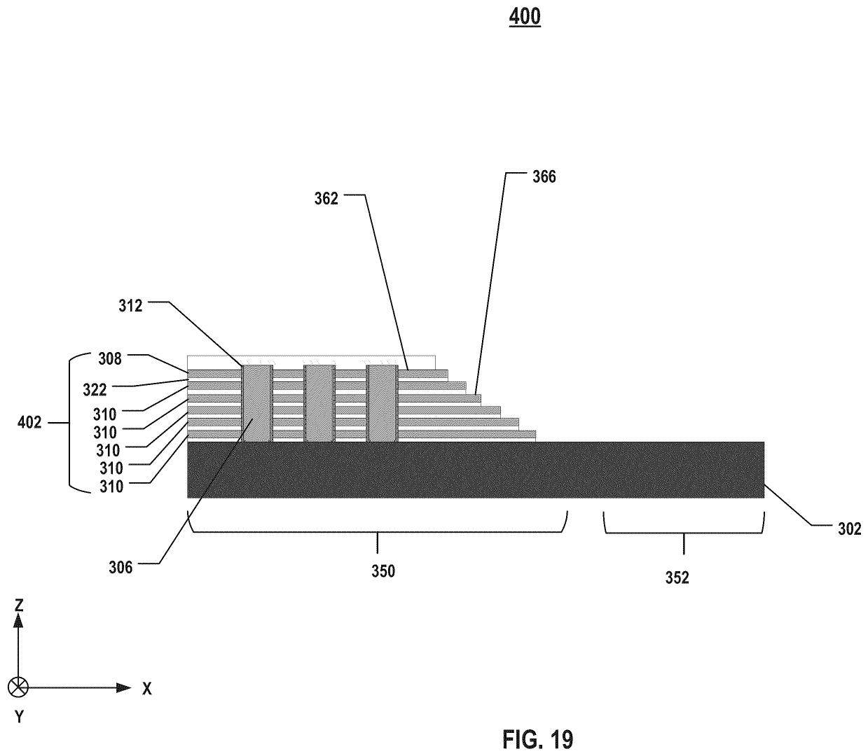

As shown in FIG. 19 and operation 2206 in FIG. 22, a portion of stack 402 on peripheral area 352 of semiconductor layer 302 is removed. In some implementations, stack 402 on peripheral area 352 of semiconductor layer 302 is removed, and a staircase structure at an edge of stack 402 on memory area 350 of semiconductor layer 302 is formed. In some implementations, the portion of stack 402 may be removed by a plurality of processes including, but not limited to, photolithography, dry/wet etch, CMP, and any other suitable processes. After the removal of the portion of stack 402, word line 362, including word line gate 308, and plate line 366, including plate line gate 310, are formed extending in the x-direction perpendicular to the z-direction.

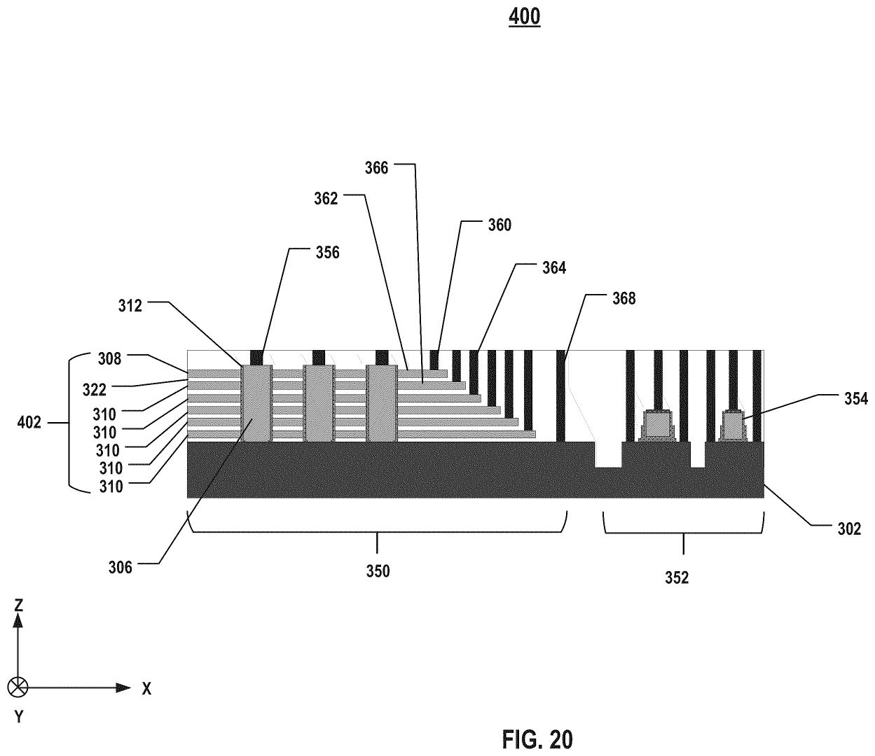

As shown in FIG. 20 and operation 2208 in FIG. 22, peripheral device 354 is formed on peripheral area 352 of semiconductor layer 302. In some implementations, peripheral device 354 is used to form the peripheral circuit including one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits may use CMOS technology which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

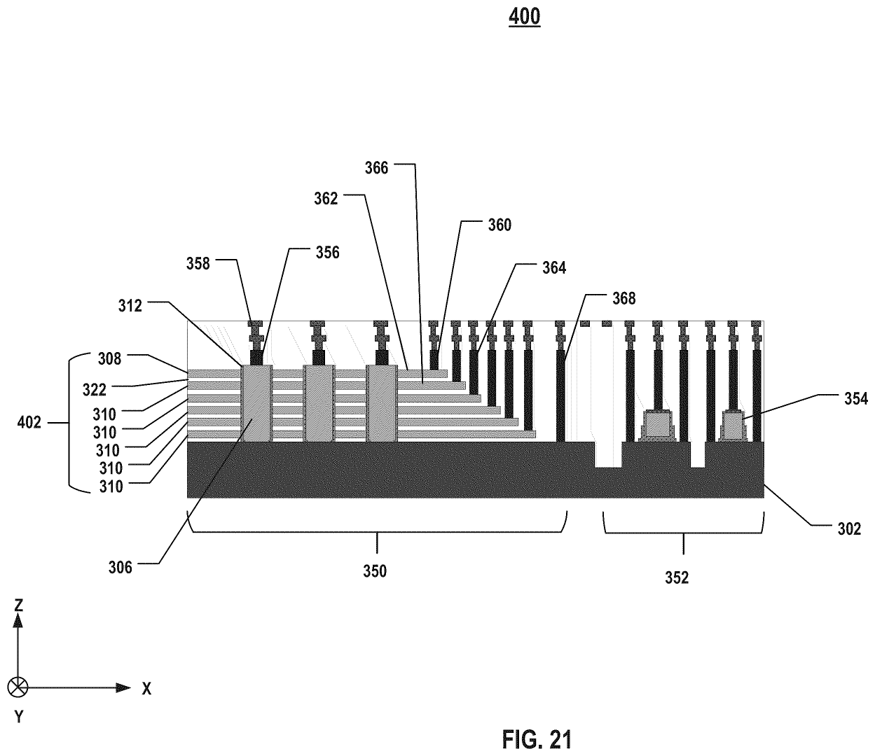

In some implementations, a plurality of contacts 356, 360, 364, and 368 are formed. In some implementations, contact 356 is formed above semiconductor body 306 in contact with second end 314, contact 360 is formed above word line 362, contact 364 is formed above plate line 366, and contact 368 is formed above semiconductor layer 302. As shown in FIG. 21 and operation 2210 in FIG. 22, bit line 358 is then formed above contact 356 extending along the y-direction perpendicular to the x-direction and the z-direction.

By utilizing the fabrication method 2200, memory device 400 may have a vertical arrangement of the source/drain terminals, which can reduce the area of the transistor as well as simplify the layout of the interconnect structures and reduce the fabrication complexity. In addition, memory device 400 does not need a capacitor storage device to store data. Furthermore, the memory cell array and the peripheral circuits can be formed on the same wafer in a side-by-side manner, and the number of wafers needed to fabricate the same number of memory devices and the complexity involved in the bonding process can be reduced.

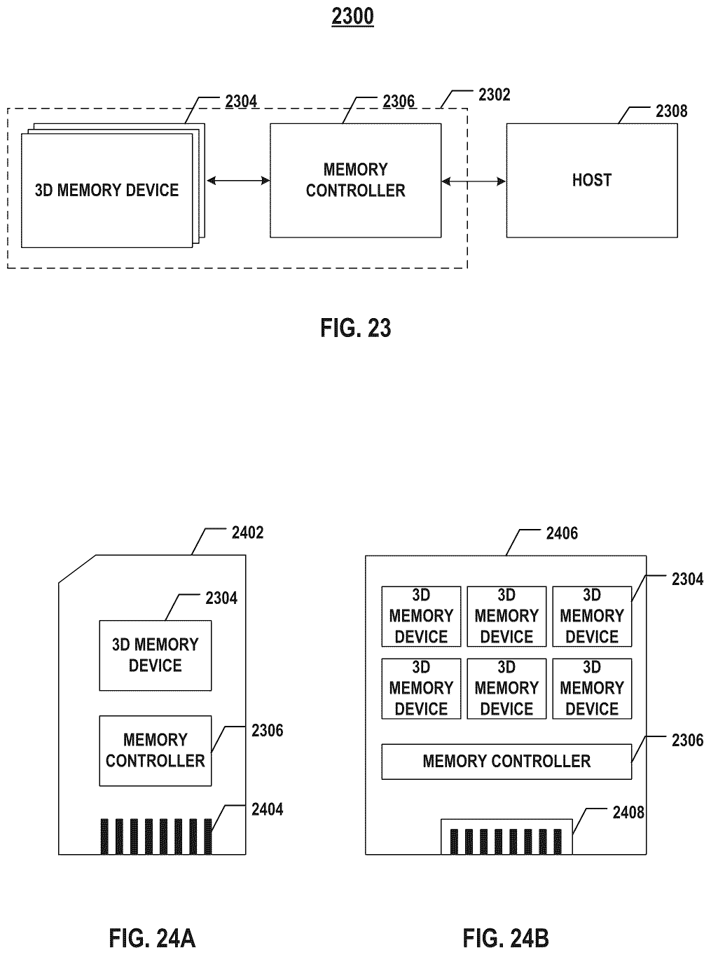

FIG. 23 illustrates a block diagram of an exemplary system 2300 having a memory device, according to some aspects of the present disclosure. System 2300 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 23, system 2300 can include a host 2308 and a memory system 2302 having one or more memory devices 2304 and a memory controller 2306. Host 2308 can be a processor of an electronic device, such as a central processing unit (CPU), or a system-on-chip (SoC), such as an application processor (AP). Host 2308 can be configured to send or receive data to or from memory devices 2304.

Memory device 2304 can be any memory device disclosed in the present disclosure. As disclosed above in detail, memory device 2304, such as a DFM device, may have a controlled and predefined discharge current in the discharge operation of discharging the bit lines. Memory controller 2306 is coupled to memory device 2304 and host 2308 and is configured to control memory device 2304, according to some implementations. Memory controller 2306 can manage the data stored in memory device 2304 and communicate with host 2308. For example, memory controller 2306 may be coupled to memory device 2304, such as memory device 300 or memory device 400 described above, and memory controller 2306 may be configured to control the operations of the memory cell, e.g., the DFM cell, through the peripheral device.

In some implementations, memory controller 2306 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 2306 is designed for operating in a high duty-cycle environment SSDs or embedded multi-media-cards (eMMCs) used as data storage for mobile devices, such as smartphones, tablets, laptop computers, etc., and enterprise storage arrays. Memory controller 2306 can be configured to control operations of memory device 2304, such as read, erase, and program operations. Memory controller 2306 can also be configured to manage various functions with respect to the data stored or to be stored in memory device 2304 including, but not limited to bad-block management, garbage collection, logical-to-physical address conversion, wear leveling, etc. In some implementations, memory controller 2306 is further configured to process error correction codes (ECCs) with respect to the data read from or written to memory device 2304. Any other suitable functions may be performed by memory controller 2306 as well, for example, formatting memory device 2304. Memory controller 2306 can communicate with an external device (e.g., host 2308) according to a particular communication protocol. For example, memory controller 2306 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 2306 and one or more memory devices 2304 can be integrated into various types of storage devices, for example, be included in the same package, such as a universal Flash storage (UFS) package or an eMMC package. That is, memory system 2302 can be implemented and packaged into different types of end electronic products. In one example as shown in FIG. 24A, memory controller 2306 and a single memory device 2304 may be integrated into a memory card 2402. Memory card 2402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 2402 can further include a memory card connector 2404 coupling memory card 2402 with a host (e.g., host 2308 in FIG. 23). In another example as shown in FIG. 24B, memory controller 2306 and multiple memory devices 2304 may be integrated into an SSD 2406. SSD 2406 can further include an SSD connector 2408 coupling SSD 2406 with a host (e.g., host 2308 in FIG. 23). In some implementations, the storage capacity and/or the operation speed of SSD 2406 is greater than those of memory card 2402.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A memory device, comprising:
a semiconductor layer;
a peripheral circuit disposed on the semiconductor layer; and
an array of memory cells disposed aside the peripheral circuit on the semiconductor layer, wherein each of the memory cells comprises:
a semiconductor body extending in a first direction, wherein a first end of the semiconductor body is in contact with the semiconductor layer;
a word line gate extending in a second direction perpendicular to the first direction;
a plate line gate extending in the second direction; and
a dielectric layer disposed between the semiconductor body and the word line gate and the plate line gate.

2. The memory device of claim 1, wherein the plate line gate comprises conductive lines extending in the second direction parallel to the word line gate.

3. The memory device of claim 1, wherein the semiconductor body and the semiconductor layer comprise a same semiconductor material.

4. The memory device of claim 1, further comprising:
a bit line extending in a third direction perpendicular to the first direction and the second direction, wherein a second end of the semiconductor body is in contact with the bit line.

5. The memory device of claim 4, further comprising:
a contact disposed between the bit line and the second end of the semiconductor body.

6. The memory device of claim 1, wherein the semiconductor layer comprises a memory area and a peripheral area, the array of memory cells is disposed in the memory area, and the peripheral circuit is disposed in the peripheral area.

7. A method for forming a memory device, comprising:
forming a peripheral circuit on a peripheral area of a first semiconductor layer;
forming a stack comprising interleaved first layers and second layers on a memory area of the first semiconductor layer;
forming a channel structure in the stack extending in a first direction; and
forming a bit line in contact with the channel structure.

8. The method of claim 7, wherein forming the stack comprising interleaved first layers and second layers on the memory area of the first semiconductor layer, comprises:
forming interleaved first dielectric layers and second dielectric layers on the peripheral area and the memory area of the first semiconductor layer.

9. The method of claim 8, further comprising:
removing the first dielectric layers and the second dielectric layers on the peripheral area.

10. The method of claim 9, further comprising:
forming a staircase structure at an edge of the stack.

11. The method of claim 8, further comprising:
replacing the second dielectric layers with at least a word line gate and a plate line gate extending in a second direction perpendicular to the first direction.

12. The method of claim 11, wherein replacing the second dielectric layers with at least the word line gate and the plate line gate extending in the second direction perpendicular to the first direction, comprises:
removing the second dielectric layers to form a plurality of cavities; and
forming the word line gate and the plate line gate in the plurality of cavities.

13. The method of claim 7, wherein forming the stack comprising interleaved first layers and second layers on the memory area of the first semiconductor layer, comprises:
forming interleaved first dielectric layers and second semiconductor layers on the memory area and the peripheral area of the first semiconductor layer.

14. The method of claim 13, wherein the first dielectric layers and the second semiconductor layers extend in a second direction perpendicular to the first direction

15. The method of claim 13, further comprising:
removing a portion of the stack on the peripheral area of the first semiconductor layer; and
forming a staircase structure at an edge of the stack on the memory area of the first semiconductor layer.

16. The method of claim 7, wherein forming the channel structure in the stack extending in the first direction, comprises:
forming a channel hole penetrating the dielectric stack to expose the semiconductor layer;
forming a third dielectric layer on sidewalls of the channel hole; and
forming a semiconductor body in the channel hole.

17. The method of claim 7, wherein forming the bit line in contact with the channel structure, comprises:
forming the bit line extending in a third direction perpendicular to the first direction and the second direction and in contact with a semiconductor body of the channel structure.

18. The method of claim 17, further comprising:
forming a contact extending in the first direction in contact with the bit line and the semiconductor body of the channel structure.

19. The method of claim 18, wherein the semiconductor body and the first semiconductor layer comprise a same semiconductor material.

20. A system, comprising:
a memory device, comprising:
a semiconductor layer;
a peripheral circuit disposed on the semiconductor layer; and
an array of memory cells disposed aside the peripheral circuit on the semiconductor layer, wherein each of the memory cells comprises:
a semiconductor body extending in a first direction, wherein a first end of the semiconductor body is in contact with the semiconductor layer;
a word line gate extending in a second direction perpendicular to the first direction;
a plate line gate extending in the second direction; and
a dielectric layer disposed between the semiconductor body and the word line gate and the plate line gate; and
a memory controller coupled to the memory device and configured to control operations of the array of memory cells through the peripheral circuit.
